(19) United States
(12) Patent Application Publication
(10) Pub. No.: US 2019/0103289 A1
(43) Pub. Date: Apr. 4, 2019

(54) TECHNIQUES TO REDUCE SUBSTRATE REFLOW WARPAGE

(71) Applicant: Intel Corporation, Santa Clara, CA (US)

(72) Inventors: Christopher David Combs, Portland, OR (US); Steven Vandervoort, Beaverton, OR (US)

(21) Appl. No.: 15/720,190

(22) Filed: Sep. 29, 2017

(51) Int. Cl. H01L 21/48; H01L 21/56; H01L 23/373; H01L 23/498; H01L 23/31; H01L 23/00

(52) U.S. Cl. CPC H01L 21/4864; H01L 21/563; H01L 23/3733; H01L 24/13; H01L 23/3128; H01L 23/49816; H01L 21/4853; H01L 23/49894

(57) ABSTRACT

Apparatus and methods are provided to reduce warpage of an integrated circuit package while reflowing solder to couple a first substrate of a first electronic device with a second substrate or second electronic device. In an example, the method can include placing an anti-warpage fixture onto the first electronic device to provide a captured electronic device, placing the captured electronic device and the anti-warpage fixture on the second substrate, and reflowing the captured electronic device to the second substrate. In certain examples, the method can include limiting a clearance distance between the first substrate and the second substrate to a minimum distance.

### TECHNICAL FIELD

The disclosure herein relates generally integrated circuit processing and more particularly, to techniques for reducing substrate warpage during solder reflow.

### BACKGROUND

As semiconductor electronics have evolved, increasing speed, reducing size, and conserving power have become some of the busiest areas of developmental focus. Incremental innovation, in each area, can hold promise of capturing, at least for a while, marketplace advantage over competitors. As component and substrate size shrink, structural resilience can weaken such that process operations can introduce issues that did not manifest on larger or thicker components. One such issue can be warpage of thinner substrates during solder reflow operations.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1A illustrates generally a cross-section of a system including an example fixture for limiting or eliminating warpage of a substrate during a reflow process of an electronic assembly.

FIG. 1B illustrates generally a cross-section of a system including an alternative example fixture for limiting or eliminating warpage of a substrate during a reflow process of an electronic assembly.

FIG. 1C illustrates generally a top-view of the example fixture resting atop a first electronic device that is resting or coupled to a second electronic device.

FIG. 2 illustrates generally a cross-section view of a system including an example anti-warpage fixture with a captured first electronic device.

FIG. 3 illustrates generally a cross-section view of a system including an example anti-warpage fixture with a captured first electronic component.

FIG. 4 illustrates generally a flowchart of an example method of preventing or limiting warpage of an integrated circuit during reflow.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Surface mount is an example of an electronic component processing technique to attach electronic components such as semiconductor devices to receptacles such as a printed circuit board (PCB) or other substrate. Many electronic components are prepared for surface mount processing by attachment of a solder pad, pin, connector, or ball grid array (BGA) to the electronic component package. Thereafter, for example, the electronic component can be mounted on a second PCB or mounted into a package-on-package (POP) semiconductor assembly, wherein the electronic component in a semiconductor package is surface mounted on or over a bottom package of the POP assembly, wherein the top package is connected to a substrate of the bottom component in the POP assembly, the substrate providing the interconnection there between and the substrate of the bottom component acting as a receptacle for both the bottom and top electronic components and forming the means for later attachment of the POP to another receptacle component.

During such attachment process, the package-on-package assembly can be exposed to high temperatures to reflow the solder connections. Yet, electronic components can warp during the temperature excursion (i.e., heating the electronic package, exposing it for a time to the high temperature, and thereafter cooling the electronic component) due to a mismatching of different thermal expansion coefficients (i.e., Coefficients of Thermal Expansion (CTEs)) of the individual materials inside the electronic component. This CTE mismatch between the individual materials inside the electronic component will cause bending or warpage of the electronic component when the assembly cools after heating. High warpage or warpage in the direction of the top and bottom components may not match, causing the solder in the solder connection to not “wet” on both components of the solder connection (i.e., make contact therewith when in the liquid form), thereby maintaining the form of a solder attached to the one component without connecting to the bottom component. This results in an electrical failure where there is one or more open connections between the electronic component and the bottom pad. In addition, warpage can also squeeze a connection together such that the solder joint spreads out. In extreme situations, the solder can spread so much that the solder can create a short between two or more solder connections.

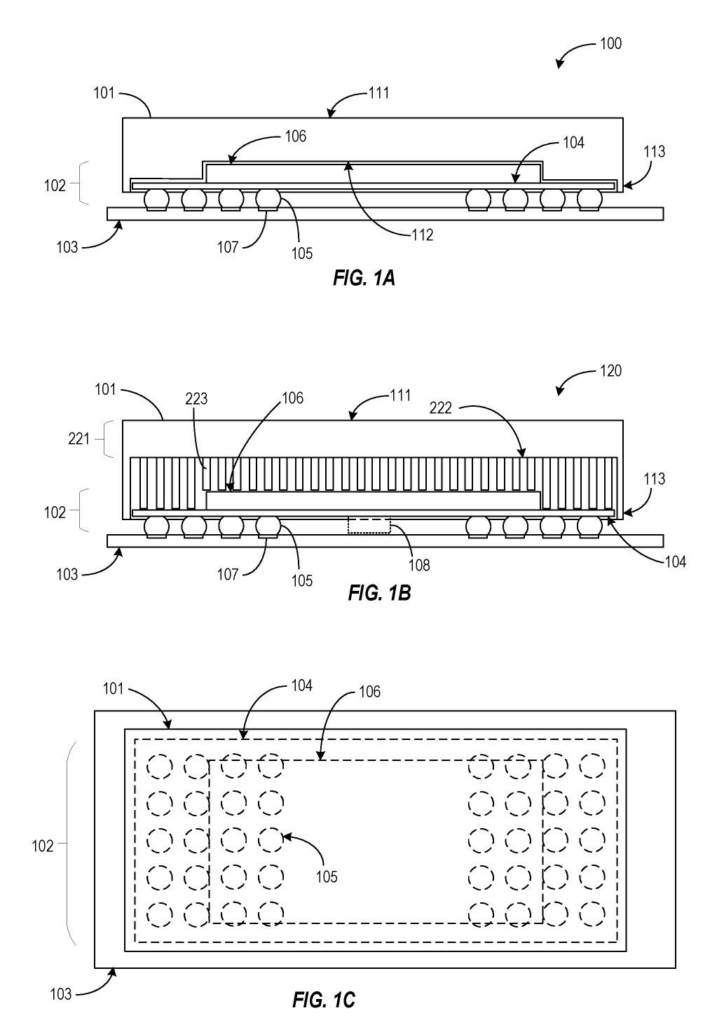

FIG. 1A illustrates generally a cross-section of a system 100 including an example fixture 101 for limiting or eliminating warpage of a substrate during a reflow process of an electronic assembly. The system can include the fixture 101, a first electronic device 102, and a second electronic device 103. The first electronic device 102 can include a substrate 104 including solder connections 105, and one or more components 106 mounted to the substrate 104. The second electronic device 103 can include solder connections, such as solder pads 107, for mounting the first electronic device 102 to the second electronic device 103. Solder connections 105 of the first electronic device 102 or the solder connections 107 of the second device 103 can include a coating of solder or solder paste that con be melted and re-solidified during a re-flow process to electrically and mechanically couple the first and second electronic devices 102, 103 together. In certain examples, the second electronic device 103 can be a much larger system than the first electronic device 102.

The fixture 101 can rest on a first electronic device 102 as the first electronic device 102 undergoes solder reflow for connection with a second electronic device 103. The weight of the fixture 101 can be enough to prevent or limit warping of the substrate 104 of the first electronic device 102 as the first component 102 and second electronic device 103 endure the thermal cycling of the reflow process. In certain examples, the fixture 101 can include a plate having a top surface 111 and a bottom surface 112. In some examples, the bottom surface 112 of the fixture 101 can includes contours that conform to the contours of the substrate 104 of the first electronic device 102, including discrete components 106 already connected to the top side of the substrate 104 of the first electronic device 102. In certain examples, the bottom surface 112 can include a frame 113 to capture the extents of the first electronic device 102. In some examples, the plate can include channels or an insulative layer to prevent or reduce the ability of the fixture from absorbing, or robbing heat from the reflow process.

FIG. 1B illustrates generally a cross-section of a system 100 including an alternative example fixture 120 for limiting or eliminating warpage of a substrate 104 during a reflow process of an electronic assembly. The fixture 120 can rest on a first electronic device 102 as the first electronic component undergoes solder reflow for connection with a second electronic device 103. The weight of the fixture 120 can be enough to prevent or limit warping of a substrate 104 of the first electronic device 102 as the first electronic device 102 and second electronic device 103 endure the thermal cycling of the reflow process. In certain examples, the fixture 120 can include a plate 221 having a top surface 111 and a bottom surface 222. In certain examples, columns 223 can extend from the bottom surface 222 of the plate 221 of the fixture 120 and each column 223 can rest on an upper surface of the first electronic device 102. In certain examples, having columns 223 can provide the fixture 120 with some thermal resistance such that the fixture 120 is less inclined to divert heat from the reflow process. For similar materials, the columns 223 can provide greater thermal resistance during the reflow process than a fixture that has a more continuous surface that rests on the first electronic device 102 during re-flow. In certain examples, the columns 223 can be of a different material that the plate 221. In such examples, the material of the plate can be selected to provide a proper weight, and the material of the columns can be selected to provide low conductive thermal transfer away from the electronic device 102. FIG. 1C illustrates generally a top-view of the example fixture 101 resting atop a first electronic device 102 that is resting or coupled to a second electronic device 103.

In certain situations, the substrate of the first electronic device 102 can be relatively long, such that the middle of the substrate 104 of the first electronic device 102 can droop toward the solder connections 107 of the second electronic device 103. In such situations, circuit board designers can optionally mount discrete components 108 to the bottom surface of the substrate 104 of the first electronic device. The optionally discreet components 108 can limit the distance between the substrate 104 of the first electronic device 102 and the solder locations of the second electronic device 103. In some examples, the discrete components 108 can include, but are not limited to, capacitors, copper balls, solder covered copper balls, or combinations thereof. In some examples, including the examples discussed below, copper balls, or solder covered copper balls, can be added to a periphery of the first electronic device to provide a stand-off at the periphery of the first electronic device 102 and to prevent drooping or squishing of solder connection near the periphery.

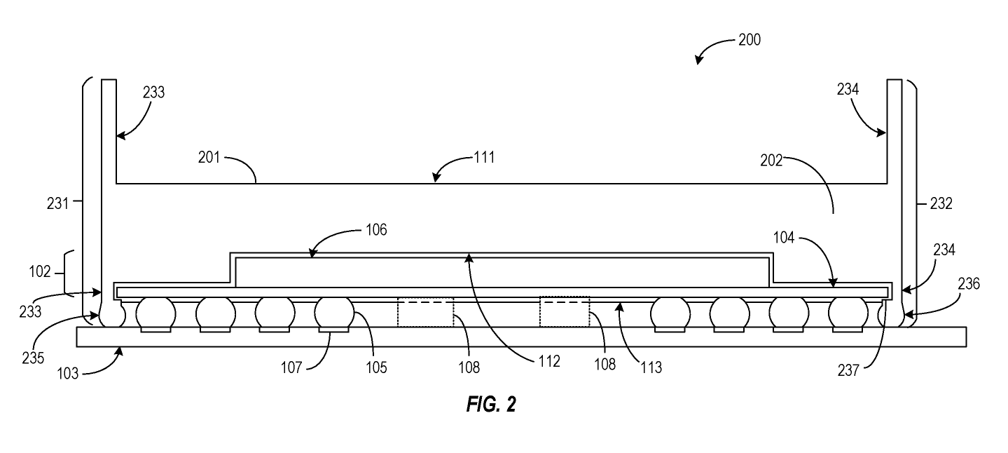

FIG. 2 illustrates generally a cross-section view of a system 200 including an example anti-warpage fixture 201 with a captured first electronic device 102. In certain examples, the fixture 201 can include a first portion 202 that can rest on the first electronic device 102 as the first electronic device 102 undergoes solder reflow for connection with a second electronic device 103. In certain examples, the weight of the first portion 202 can be enough to prevent or limit warping of a substrate 104 of the first electronic device 102 as the first electronic device 102 and second electronic device 103 endure the thermal cycling of the reflow process. In certain examples, the first portion 202 can include a plate having a top surface 111 and a bottom surface 112. In some examples, the bottom surface 112 of the plate can include contours that conform to the contours of the substrate 104 of the first electronic device 102, including discrete components 106 already connected to the top side of the substrate 104 of the first electronic device 102. In certain examples, the bottom surface 112 can include a frame 113 to capture the extents of the first electronic device 102. In some examples, the plate can include channels or an insulative layer to prevent reduce the ability of the fixture from absorbing, or robbing heat from the reflow process.

In certain examples, the fixture 201 can include a pair of clips 231, 232 extending from the first portion 202. Each clip 231, 232 can have a vertical portion 233, 234 extending directly from the first portion 202 or the plate of the fixture 201. Each clip 231, 232 can include a clip end 235, 236 extending from the vertical portion 233, 234 at an end of the vertical portion 233, 234 distal from the first portion 202. In certain examples, the lower surface 112 of the first portion 202 or the plate, the vertical portion 233, 234 of each clip 231 232, and the corresponding clip end 235, 236 can partially enclose a portion of the first electronic device 102 when the first portion 202 is at rest on the first electronic device 102. In certain examples, the process of getting, for example, a substrate 104 of the first electronic device 102 enclosed using the clip ends 235, 236 can be referred to as “clipping” the fixture 201 to the first electronic device 102. In certain examples, a vertical dimension of the clip end 235, 236 can be used to provide a minimum stand-off dimension between a lower surface of the substrate 104 first electronic device 102 and an upper surface of the second electronic device 103. In use, the conformal shape of the first portion 202 of the fixture 201, along with the weight of the fixture 201, press down on the first electronic device 102 during reflow and resist, via gravity, forces that would otherwise warp either the substrate 104 of the first electronic device 102, the upper surface of the second electronic device 103, or both. In addition, the weight of the fixture 201 can squish the solder connections 105. Without some limiting means, it may be possible for the compression or squishing of the solder connections 105 to go too far such that the solder extends to other connections not intended to be soldered or connected. In certain examples, the clip end 235, 236 can include a ledge 237 that can provide the limiting means, a minimum clearance between the bottom of the substrate 104 and the second electronic device 103, to prevent migration of a solder connection 105 to include other unintended connections.

During reflow heating, the solder connections 105, 107 can eventually soften. Pressure, for example, via the weight of the first component 102, and/or the weight of the fixture 201, can begin to compress the softened solder. The substrate 104 of the first electronic device 102, without some limiting means, can completely sandwich the molten solder which, in turn, the solder can extend out with declining distance between the substrate 104 of the first electronic device 102 and the second electronic device 103. However, the lower surface of the substrate 104 of the first electronic device 102 can be supported on a ledge 237 of the clip end 235, 236 and can physically limit the distance between the substrate 104 of the first electronic device 102 and the connection pads 107 of the second electronic device 103. After reflow, clip extensions, or the upper ends of the vertical portions 233, 234, can be pinched together to “un-clip” the clip ends 235, 236 from the first electronic device 102.

In certain situations, a substrate 104 of the first electronic device 102 can be relatively long, such that even with use of the clip ends 235, 236 to limit the distance between the substrate 104 of the first electronic device 102 and the solder connections 107 of the second electronic device 103, the middle of the substrate 104 of the first electronic device 102 can droop toward the solder connections 107 of the second electronic device 103. In such situations, circuit board designers can optionally mount discrete components 108 to the bottom surface of the substrate 104 of the first electronic device 102 such that the discrete component(s) 108 can limit the distance between the substrate 104 of the first electronic device 102 electronic device 102 and the solder locations 107 of the second electronic device 103. In some examples, the discrete components 108 can include, but are not limited to, capacitors, copper balls, solder covered copper balls, or combinations thereof.

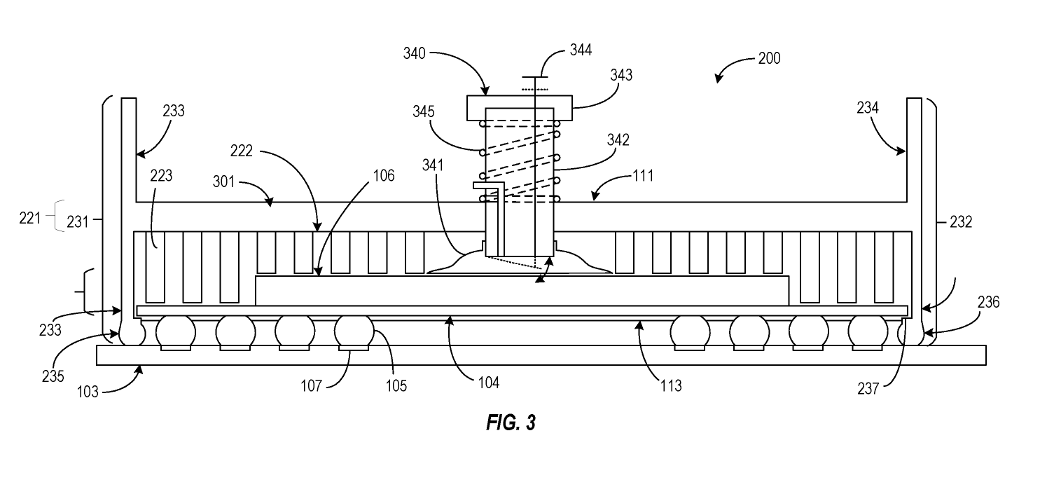

FIG. 3 illustrates generally a cross-section view of a system 300 including an example anti-warpage fixture 301 with a captured first electronic component 102. In certain examples, the fixture 301 can include a first portion or plate 221 that can rest on the first electronic device 102 as the first electronic device 102 undergoes solder reflow for connection with a second electronic device 103. In certain examples, the weight of the fixture 301 can be enough to prevent or limit warping of a substrate 104 of the first electronic device 102 as the first electronic device 102 and second electronic device 103 endure the thermal cycling of the reflow process. In certain examples, the fixture 301 can include a plate 221 having a top surface 111 and a bottom surface 222. In some examples, the bottom surface 222 of the plate 221 can includes contours that conform to the contours of the substrate of the first electronic device 102, including discrete components 106 already connected to the top side of the substrate 104 of the first electronic device 102. In certain examples, the fixture 301 can include a frame 113 to capture the extents of the first electronic device 102. In some examples, the plate 221 can include channels or an insulative layer to prevent reduce the ability of the fixture 301 from absorbing, or robbing heat from the reflow process.

In certain examples, columns 223 can extend from the bottom surface 222 of the plate 221 of the fixture 120 and each column 223 can rest on an upper surface of the first electronic device 102. In certain examples, having columns 223 can provide the fixture 301 with some thermal resistance such that the fixture 301 is less inclined to divert heat from the reflow process. For similar materials, the columns 223 can provide greater thermal resistance during the reflow process than a fixture that has a more continuous surface that rests on the first electronic device 102 during re-flow.

In certain examples, the fixture 301 can include a pair of clips 231, 232 extending from the plate 221. Each clip 231, 232 can have a vertical portion 233, 234 extending directly from the plate 221 of the fixture 301. Each clip 231 232 can include a clip end 235, 236 extending from the vertical portion 233, 234 at an end of the vertical portion 233, 234 distal from the plate 221. In certain examples, the lower surface 222 of the plate 221, the vertical portion 233, 234 of each clip 231, 232, and the corresponding clip end 235, 236 can partially enclose a portion of the first electronic device 102 when the plate 221 is at rest on the first electronic device 102. In certain example, the process of getting, for example, a substrate 104 of the first electronic device 102 enclosed using the clip end 235, 236 can be referred to as “clipping” the fixture 301 to the first electronic device 102. In certain examples, a vertical dimension of the clip end 235, 236 can be used to provide a minimum stand-off dimension between a lower surface of the first electronic device 102 and an upper surface of the second electronic device 103. In use, the conformal shape of the plate 221, or columns 223, of the fixture 301, along with the weight of the fixture 301, can press down on the first electronic device 102 during reflow and resist, via gravity, forces that would otherwise warp either the substrate 104 of the first electronic device 102, the upper surface of the second electronic device 103, or both. In addition, the weight of the fixture 301 can squish the solder connections 105, 107. Without some limiting means, it may be possible for the compression or squishing of the solder connections 105, 107 to go too far such that the solder extends to other connections not intended to be soldered or connected together. In certain examples, the clip end 235, 236 can include a ledge 237 that can provide the limiting means, a minimum clearance between the bottom of the substrate 104 and the second electronic device 103, to prevent migration of a solder connection 105 to include other unintended connections. After reflow, the upper ends of the vertical portions 233, 234 can be pinched together to “un-clip” the clip ends 235, 236 from the first electronic device 102.

During reflow heating, the solder connections 105, 107 can eventually soften. Pressure, for example, via the weight of the first electronic device 102, and/or the weight of the fixture 301, can begin to compress the softened solder. The substrate 104 of the first electronic device 102, without some limiting means, can completely sandwich the molten solder which, in turn, can force the molten solder to expand out between the substrate 104 of the first electronic device 102 and the second electronic device 103. Such expansion can lead to unintended short-circuits between solder connections. However, the lower surface of the substrate 104 of the first electronic device 102 can be supported on a ledge 237 of the clip end 235, 236 and can physically limit the distance between the substrate 104 of the first electronic device 102 and the connection pads 107 of the second electronic device 103.

In certain situations, the substrate 104 of the first electronic device 102 can be relatively long or wide, such that even with use of the clip ends 235, 236 to limit the distance between the substrate 104 of the first electronic device 102 and the solder connections 107 of the second electronic device 103, the middle of the substrate 104 of the first electronic device 102 can warp or droop. In certain examples, the fixture 301 can include an opening in the plate 221 and a plunger or vacuum mechanism 340 can occupy the opening. In certain examples, the vacuum mechanism can include a vacuum cup 341, a shaft 342, a shaft end 343, a vacuum release mechanism 344, and a spring 345.

In an example, as the fixture 301 is placed on the first electronic device 102, the vacuum cup 341 can be engaged with a top surface 111 of the first electronic device 102 and air can be forced out of the vacuum cup 341 such that the vacuum cup 341 is vacuum attached to the top surface 111 of the first electronic device 102. In some examples, a pick-n-place machine can place the fixture 301 on the first electronic device 102 after the first electronic device 102 is placed on the second electronic device 103. In some examples, a pick-n-place machine can place the fixture 301 on the first electronic device 102 before the first electronic device 102 is placed on the second electronic device 103. It is understood that a pick-n-place machine can also be used to interact with the examples of FIGS. 1 and 2.

As the reflow process proceeds, a spring 345 of the vacuum mechanism 340 can apply pressure to the vacuum cup 341 that can, in turn, hold the top surface of first electronic device 102 against the plate 221 of the fixture 301 or against columns 223 attached to the plate 221 of the fixture 301, thus resisting a tendency for at least a middle portion of the substrate 104 of first electronic device 102 to warp or droop. In certain examples, the spring 345 can be compressed between the shaft end and a top surface 111 of the first electronic device 102. After the reflow process, a vacuum release mechanism 344 can be actuated to open a valve at the suction cup 341 to, in turn, release the vacuum of the vacuum cup 341 and allow the fixture 301 to be removed from the first electronic device 102.

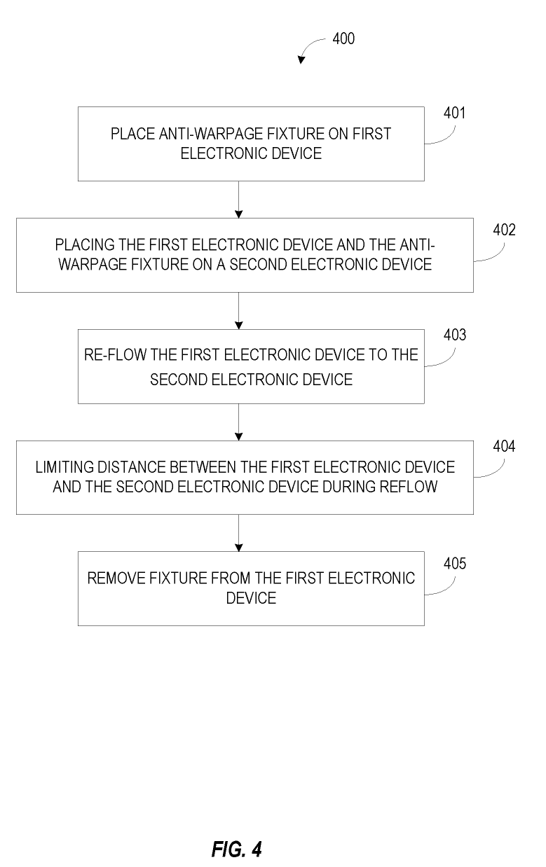

FIG. 4 illustrates generally a flowchart of an example method 400 of preventing or limiting warpage of an integrated circuit during reflow. The method can include, at 401, placing an anti-warpage fixture onto a first integrated circuit or electronic device In some examples, the anti-warpage fixture is intended to add weight on top of the integrated circuit such that during the reflow to attached the integrated circuit to a second substrate, the weigh can stiffen and flatten the integrated circuit to prevent for example the outer edge areas of the integrated circuit from warping away from the second substrate while simultaneously preventing interior areas of the integrated circuit from dropping toward the second substrate.

At 402, the first electronic device and the anti-warpage fixture can be placed on top of a second substrate. In some example, the additional weight and conforming surface of the anti-warpage fixture can act to stiffen the thin substrate of the integrated circuit. Such stiffening can prevent, for example, the middle of the substrate of the integrated circuit from drooping during the reflow as well as prevent the edges of the substrate of the integrated circuit from warping away from the second substrate during the reflow.

In some examples, the fixture can clip to the integrated circuit package. In some examples, anti-warpage fixture can include two or more clips that extend to capture the integrated circuit. In certain examples, the clips can include clip ends that limit how close the substrate of the integrated circuit can get an upper surface of the second substrate. Such action during reflow can prevent or limit warpage of the integrated circuit. In some examples, the clip ends can work in cooperation with components mounted to the second substrate, components mounted to the bottom of the integrated circuit, or combinations thereof, to hold a substrate of the integrated circuit flat, at least during the reflow.

At 403, the first electronic device and the second substrate can be reflowed to solder the integrated circuit package to the second substrate.

At 404, during the reflow, the distance between the bottom of the first electronic device and the connection surface of the second electronic device can be limited to a minimum distance. In certain examples, discrete components mounted to either the bottom side of the first integrated circuit or to the top side of the second substrate can provide a hard minimum distance limit. In some examples, as discussed above, the fixture can include clips with clip ends designed to limit the distance between the bottom of the first electronic device and the connection surface of the second electronic device. In some examples, as discussed above, the fixture can include a spring-loaded vacuum mechanism designed to limit the distance between the bottom of the first electronic device and the connection surface of the second electronic device. Such a limit can eliminate or reduce warpage of the first integrated circuit. In addition, the minimum distance limit can ensure that a substantially uniform distance between the bottom of the first electronic device and the solder connections of the second electronic device is maintained across the corresponding surfaces of each. Such uniform distance can prevent solder connections from squishing to far that the solder shorts nearby connections or that, for example, a substrate of either electronic device warps away from each other such that the distance between the solder connections of each device is greater than can be spanned by the solder.

At 405, the fixture can be removed from the first electronic device. In certain examples, removing the fixture can include lifting the fixture from the first electronic device. In some examples, in addition to lifting the fixture, pressure may be applied to vertical portions of clips of the fixture to “un-clip” the fixture from the first electronic device. In some examples, in addition to lifting or “un-clipping”, a vacuum release mechanism can be actuated to release a vacuum connection between the fixture and the first electronic device.

### Additional Notes

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are legally entitled.

What is claimed is:

1. An apparatus for limiting warpage of an integrated circuit package during solder reflow, the apparatus comprising:
a first portion configured to rest on a first electronic device of the integrated circuit package opposite a bottom surface of the first electronic device, the first electronic device comprising a first substrate, and an integrated circuit electrically coupled to the first substrate, wherein a bottom surface of the first substrate includes a connector for electrically coupling to a second substrate during the solder reflow, and wherein the bottom surface of the first substrate forms the bottom surface of the first electronic device;
a pair of clips extending from the first portion, each clip having a vertical portion extending directly from the first portion and a clip end extending from the vertical portion distal from the first portion, wherein a lower surface of the first portion, the vertical portion of each clip, and the corresponding clip end are configured to partially enclose a portion of the integrated circuit package when the first portion is at rest on the first electronic device; and
wherein each clip is configured to provide a minimum stand-off distance between the first substrate and the second substrate during the solder reflow.

2. The apparatus of claim 1, wherein the clip end includes a ledge, the ledge configured to support a lower surface of the first substrate.

3. The apparatus of claim 1, wherein the first portion includes:
a plate having an upper surface, a lower surface, and a lower surface structure, the lower surface structure including a plurality of columns configured to interface with upper surfaces of the first electronic device when the apparatus rests on the first electronic device, the columns configured to reduce heat reception of the apparatus during the solder reflow compared to a single, substantially planer, coextensive bottom surface.

4. The apparatus of claim 3, wherein the plurality of columns extend from the bottom surface of the plate away from the top surface.

5. The apparatus of claim 4, wherein the plurality of columns include a first column configured to rest on an upper surface of the first electronic device.

6. The apparatus of claim 3, wherein the plurality of columns include a first column configured to rest on an upper surface of the first substrate.

7. The apparatus of claim 1, wherein the first portion includes:
a plate having an upper surface and a lower surface; and
an opening extending from the upper surface to the lower surface.

8. The apparatus of claim 7, including a plunger captured within the opening, the plunger including a suction cup, the suction cup configured to vacuum capture an upper surface of the first electronic device.

9. The apparatus of claim 8, including a spring configured to apply upward force on the plunger to bias the plunger and to pull a captured electronic device toward the lower surface of the plate.

10. The apparatus of claim 8, wherein the suction cup includes a vacuum release mechanism to allow the suction cup to release a vacuum hold of the captured electronic device.

11. The apparatus of claim 10, wherein the vacuum release mechanism includes a vacuum release valve configured to interface with a pick-and-place machine.

12. A method of reducing warpage of an integrated circuit package while reflowing solder to couple a first substrate of a first electronic device with a second substrate, the method comprising:
placing an anti-warpage fixture onto the first electronic device to provide a captured electronic device;
placing the captured electronic device and the anti-warpage fixture on the second substrate;
reflowing the captured electronic device to the second substrate; and
wherein the reflowing includes limiting a minimum offset distance between the first substrate and the second substrate.

13. The method of claim 12, wherein, the limiting a minimum offset distance includes limiting a minimum offset distance using a clip end of the anti-warpage fixture.

14. The method of claim 12, wherein, the limiting a minimum offset distance includes limiting a minimum offset distance using a discrete component attached to a bottom side of the first substrate.

15. The method of claim 14, wherein the discrete component includes a capacitor.

16. The method of claim 14, wherein the discrete component includes a copper-based stand-off.

17. The method of claim 16, wherein the limiting a minimum offset distance includes attaching a cobber based ball to a bottom side of the first substrate at a periphery of the first substrate.

18. The method of claim 12, wherein placing an anti-warpage fixture onto the first electronic device includes resting weight of the anti-warpage fixture on the first electronic device.

19. The method of claim 12, wherein placing an anti-warpage fixture onto the first electronic device includes enclosing a portion of the first electronic device using a clip of the anti-warpage fixture.

20. The method of claim 12, including unclipping the first substrate from the anti-warpage fixture, wherein the unclipping includes pinching clip extensions toward each other, the clip extensions extending away from a main portion of the anti-warpage fixture in a direction opposite of the direction the clip ends extend from the main portion.

21. The method of claim 12, wherein the placing an anti-warpage fixture onto the first electronic device includes:
extending a plunger through an opening in the anti-warpage fixture;
applying vacuum pressure to an upper surface of the integrated circuit package via a suction cup of the plunger;
retracting the plunger to press the upper surface of the first electronic device against a lower surface of the anti-warpage fixture.
